(19) United States
(12) Patent Application Publication
(10) Pub. No.: US 2024/0162686 A1
(43) Pub. Date: May 16, 2024

(54) SEMICONDUCTOR LASER

(71) Applicant: SONY GROUP CORPORATION, TOKYO (JP)

(72) Inventors: YUICHIRO KIKUCHI, KUMAMOTO (JP); HIDEKAZU KAWANISHI, TOKYO (JP); MAKOTO OOTA, KUMAMOTO (JP); HIDEKI WATANABE, TOKYO (JP)

(21) Appl. No.: 18/550,808

(22) PCT Filed: Jan. 14, 2022
(86) PCT No.: PCT/JP2022/001107

§ 371 Date: Sep. 15, 2023

(30) Foreign Application Priority Data
Mar. 25, 2021 (JP) 2021-051410

(51) Int. Cl. H01S 5/323; H01S 5/042; H01S 5/22

(52) U.S. Cl. CPC H01S 5/323; H01S 5/04256; H01S 5/22

(57) ABSTRACT

To provide a semiconductor laser capable of further improving reliability. Provided is a semiconductor laser including a substrate, a first cladding layer of a first conductivity type, an active layer, a second cladding layer of a second conductivity type, and a pad metal in this order, in which an upper portion of the pad metal on a side of the pad metal opposite to a side closer to the substrate and a side portion of the pad metal are covered with an insulating film and a barrier metal, and the barrier metal and a bonding metal are disposed in this order on the pad metal on the side of the pad metal opposite to the side closer to the substrate.

### TECHNICAL FIELD

The present technology relates to a semiconductor laser.

### BACKGROUND ART

In recent years, there has been an increasing demand for semiconductor lasers as light sources for high-density optical disk devices, laser beam printers, full-color displays, and the like, and development of semiconductor lasers has been actively conducted.

For example, Patent Document 1 proposes a semiconductor laser element using a barrier metal layer.

### CITATION LIST

### Patent Document

Patent Document 1: Japanese Patent Application Laid-Open No. 2006-100369

### SUMMARY OF THE INVENTION

### Problems to be Solved by the Invention

However, there is a possibility that further improvement in reliability is not achieved with the technique proposed in Patent Document 1.

Therefore, the present technology has been made in view of such a situation, and a main object thereof is to provide a semiconductor laser capable of further improving reliability.

### Solution to Problems

As a result of diligent research to solve the above-described object, the present inventors have succeeded in further improving the reliability, and have completed the present technology.

That is, the present technology provides a semiconductor laser including a substrate, a first cladding layer of a first conductivity type, an active layer, a second cladding layer of a second conductivity type, and a pad metal in this order, in which an upper portion of the pad metal on a side of the pad metal opposite to a side closer to the substrate and a side portion of the pad metal are covered with an insulating film and a barrier metal, and the barrier metal and a bonding metal are disposed in this order on the pad metal on the side of the pad metal opposite to the side closer to the substrate.

In the semiconductor laser according to the present technology, the insulating film may cover a part of the upper portion and the side portion of the pad metal, and the barrier metal may cover a part of the upper portion of the pad metal.

In the semiconductor laser according to the present technology, the insulating film may cover a part of the upper portion and the side portion of the pad metal, the barrier metal may cover a part of the upper portion of the pad metal, and a part of the insulating film covering the part of the upper portion of the pad metal and a part of the barrier metal covering the part of the upper portion of the pad metal may be formed in this order from a side closer to the pad metal.

In the semiconductor laser according to the present technology, the insulating film may cover the side portion of the pad metal, and the barrier metal may cover the upper portion of the pad metal.

In the semiconductor laser according to the present technology, the insulating film may cover a part of the upper portion and the side portion of the pad metal, the barrier metal may cover a part of the upper portion of the pad metal, and an end portion of the insulating film covering the part of the upper portion of the pad metal and an end portion of the barrier metal covering the part of the upper portion of the pad metal may be in contact with each other.

In the semiconductor laser according to the present technology, the insulating film may cover a part of the side portion of the pad metal, and the barrier metal may cover the upper portion and a part of the side portion of the pad metal.

In the semiconductor laser according to the present technology, a first guide layer may be disposed between the first cladding layer and the active layer, and a second guide layer may be disposed between the second cladding layer and the active layer.

In the semiconductor laser according to the present technology, a contact layer and a second electrode may be disposed in this order from the side closer the substrate between the second cladding layer and the pad metal, and the second electrode may be a transparent conductive film.

In the semiconductor laser according to the present technology, the insulating film may have a laminated structure including at least two layers, and at least one layer of the at least two layers of the insulating film may be a SiN layer.

In the semiconductor laser according to the present technology, the barrier metal may have a laminated structure including at least two layers, and at least one layer of the at least two layers of the barrier metal may be a Ti layer.

The semiconductor laser according to the present technology may be a nitride semiconductor laser.

According to the present technology, it is possible to further improve the reliability. Note that the effects described herein are not necessarily limitative, and any of the effects described in the present disclosure may be exhibited.

### BRIEF DESCRIPTION OF DRAWINGS

FIG. 1 is a view illustrating a configuration example of a semiconductor laser according to a first embodiment to which the present technology is applied.

FIG. 2 is a view for describing a method for manufacturing a semiconductor laser according to a second embodiment to which the present technology is applied.

FIG. 3 is a view for describing the method for manufacturing a semiconductor laser according to the second embodiment to which the present technology is applied.

FIG. 4 is a view for describing the method for manufacturing a semiconductor laser according to the second embodiment to which the present technology is applied.

FIG. 5 is a view for describing the method for manufacturing a semiconductor laser according to the second embodiment to which the present technology is applied.

FIG. 6 is a view illustrating a configuration example of a semiconductor laser manufactured according to the method for manufacturing a semiconductor laser of the second embodiment to which the present technology is applied.

### MODE FOR CARRYING OUT THE INVENTION

Hereinafter, preferred modes for carrying out the present technology will be described. Embodiments to be described below illustrates examples of representative embodiments of the present technique, and the scope of the present technique is not narrowed by them. Note that, in the drawings, “upper” means an upper direction or an upper side in the drawings, “lower” means a lower direction or a lower side in the drawings, “left” means a left direction or a left side in the drawings, and “right” means a right direction or a right side in the drawings unless otherwise specified. Furthermore, in description using the drawings, the same or equivalent elements or members are designated by the same reference signs, and duplicate description will be omitted unless there is a special circumstance.

Note that the description will be made in the following order.
1. Outline of Present Technology
2. First Embodiment (Example 1 of Semiconductor Laser)
3. Second Embodiment (Example 1 of Method for Manufacturing Semiconductor Laser and Example 2 of Semiconductor Laser)

### 1. Outline of Present Technology

First, an outline of the present technology is described. The present technology relates to a semiconductor laser.

A semiconductor laser, for example, a pure blue semiconductor laser (LD) using a nitride-based compound semiconductor material has been developed for applications such as a laser display and an on-vehicle headlight source. An output of a high-output semiconductor laser may be saturated due to the influence of self-heating. Therefore, mounting is performed by junction-down mounting that is excellent in heat radiation property. In the junction-down mounting, a solder on a heat sink side may diffuse to an electrode of a chip due to the influence of heat during the mounting. Therefore, it is necessary to provide a barrier layer for preventing the diffusion. Materials for preventing the diffusion of the solder have been studied for the barrier layer, and, for example, molybdenum (Mo) and titanium (Ti) may be used, and platinum (Pt) and tungsten (W) which are high-melting-point material may also be used.

However, even when an electrode of an energized section is covered with a material having a barrier property as described above, there is a possibility that the diffusion proceeds further than a side portion (side surface) of the electrode if the step coverage of the side portion (side surface) of the electrode is insufficient.

The present technology has been made in view of the above. The present technology can provide a semiconductor laser including a substrate, a first cladding layer of a first conductivity type, an active layer, a second cladding layer of a second conductivity type, and a pad metal in this order, in which an upper portion of the pad metal on a side of the pad metal opposite to a side closer to the substrate and a side portion of the pad metal are covered with an insulating film and a barrier metal, and the barrier metal and a bonding metal are disposed in this order on the pad metal on the side opposite to the side of the pad metal closer to the substrate.

Note that, in a case where the first cladding layer of the first conductivity type is an n-type cladding layer, the second cladding layer of the second conductivity type is a p-type cladding layer, and the substrate is an n-type substrate. On the other hand, in a case where the first cladding layer of the first conductivity type is a p-type cladding layer, the second cladding layer of the second conductivity type is an n-type cladding layer, and the substrate is a p-type substrate. Furthermore, in a case where the first cladding layer of the first conductivity type and/or the second cladding layer of the second conductivity type include a GaN-based material, the substrate may be an insulating substrate (for example, a sapphire substrate).

Six aspects in which the upper portion and the side portion of the pad metal are covered with the insulating film and the barrier metal will be described as follows.

(Aspect 1)

The insulating film covers a part of the upper portion and the side portion of the pad metal, and the barrier metal covers a part of the upper portion of the pad metal.

(Aspect 2)

The insulating film covers a part of the upper portion and the side portion of the pad metal, the barrier metal covers a part of the upper portion of the pad metal, and a part of the insulating film covering the part of the upper portion of the pad metal and a part of the barrier metal covering the part of the upper portion of the pad metal are formed in this order from the pad metal side.

(Aspect 3)

The insulating film covers the side portion of the pad metal, and the barrier metal covers the upper portion of the pad metal.

(Aspect 4)

The insulating film covers a part of the upper portion and the side portion of the pad metal, the barrier metal covers a part of the upper portion of the pad metal, and a part of the barrier metal covering the part of the upper portion of the pad metal and a part of the insulating film covering the part of the upper portion of the pad metal are formed in this order from the pad metal side.

(Aspect 5)

The insulating film covers a part of the upper portion and the side portion of the pad metal, the barrier metal covers a part of the upper portion of the pad metal, and an end portion of the insulating film covering the part of the upper portion of the pad metal and an end portion of the barrier metal covering the part of the upper portion of the pad metal are in contact with each other. Note that an end surface of the insulating film covering the part of the upper portion of the pad metal and an end surface of the barrier metal covering the part of the upper portion of the pad metal may be joined.

(Aspect 6)

The insulating film covers a part of the side portion of the pad metal, and the barrier metal covers the upper portion of the pad metal and a part of the side portion.

In the present technology, a semiconductor material used for the semiconductor laser is not particularly limited. Examples of the semiconductor laser according to the present technology include a nitride semiconductor laser including a Group III-V nitride semiconductor material such as GaN.

A substrate constituting the nitride semiconductor laser includes a compound semiconductor, for example, a Group III-V nitride semiconductor such as GaN. Here, the “Group III-V nitride semiconductor” refers to one containing at least one of Group 3B elements in the short-period periodic table and at least N of Group 5B elements in the short-period periodic table. Examples of the Group III-V nitride semiconductor include gallium nitride-based compounds containing Ga and N. Examples of the gallium nitride-based compounds include GaN, AlGaN, AlGaInN, and the like. The Group III-V nitride semiconductor may be doped with an n-type impurity of a Group IV or Group VI element, such as Si, Ge, O, or Se, or a p-type impurity of a Group II or Group IV element, such as Mg, Zn, or C, as necessary.

A semiconductor layer constituting the nitride semiconductor laser includes, for example, a Group III-V nitride semiconductor, and is formed by, for example, an epitaxial crystal growth method such as a metal organic chemical vapor deposition (MOCVD) method with the main surface of the substrate as a crystal growth surface. This semiconductor layer includes an active layer that forms a light emitting region. Specifically, the semiconductor layer includes, for example, an n-type cladding layer, the active layer, a p-type cladding layer), a contact layer (for example, a p-type contact layer), and the like in order from the substrate side. The n-type cladding layer includes, for example, AlGaN. The active layer has, for example, a multiple quantum well structure in which well layers and barrier layers formed with GaInNs at different composition ratios are alternately laminated. The p-type cladding layer includes, for example, AlGaN. The contact layer includes, for example, GaN. Note that the semiconductor layer may further include a layer other than the layers described above (for example, a buffer layer, an n-side guide layer, a p-side guide layer, or the like).

Furthermore, examples of the semiconductor laser according to the present technology include a semiconductor laser (infrared laser) using an AlGaAs-based material.

In this semiconductor laser (infrared laser), materials of n-GaAs, n-AlGaAs, AlGaAs, p-AlGaAs, and GaAs are used for a substrate, an n-type cladding layer, an active layer, a p-type cladding layer, and a contact layer, respectively.

In the semiconductor laser, it may be difficult to obtain a high output due to the influence of heat generation of an element. Examples of solutions thereof include execution of junction-down mounting in which a semiconductor laser light emitting unit is assembled onto a member side having a high heat dissipation property such as a heat sink. In the junction-down mounting, a Sn solder on the heat sink side may diffuse to an electrode of the element to cause degradation. As a countermeasure thereof, a material having a barrier property against Sn may be selected. Note that there remains a possibility that the diffusion cannot be prevented even with the material having the barrier property depending on the coverage of a step portion of the element.

In the present technology, the upper portion and the side portion of the pad metal are covered with the insulating film and the barrier metal. For example, the insulating film can be formed on the side portion (side surface) of the pad metal by a deposition method with good coverage such as sputtering, and then, the barrier metal can be deposited. For example, the pad metal has the side surface being protected by the insulating film having poor wettability of the Sn solder, and the upper surface on which the barrier metal prevents the diffusion.

The insulating film may have a laminated structure including at least a SiN layer, or may be a single layer of SiN. The barrier metal may include a Sn-based solder, such as titanium (Ti), platinum (Pt), molybdenum (Mo), or tungsten (W), and a layer (for example, a metal layer) containing a material that is less likely to be thermally diffused, and may have a laminated structure in which a plurality of layers is laminated, or have a single-layer structure including one layer.

The above description is the outline of the present technology. Hereinafter, the preferred modes for carrying out the present technology will be specifically described in detail with reference to the drawings. Embodiments to be described below illustrates examples of representative embodiments of the present technique, and the scope of the present technique is not narrowed by them.

### 2. First Embodiment (Example 1 of Semiconductor Laser)

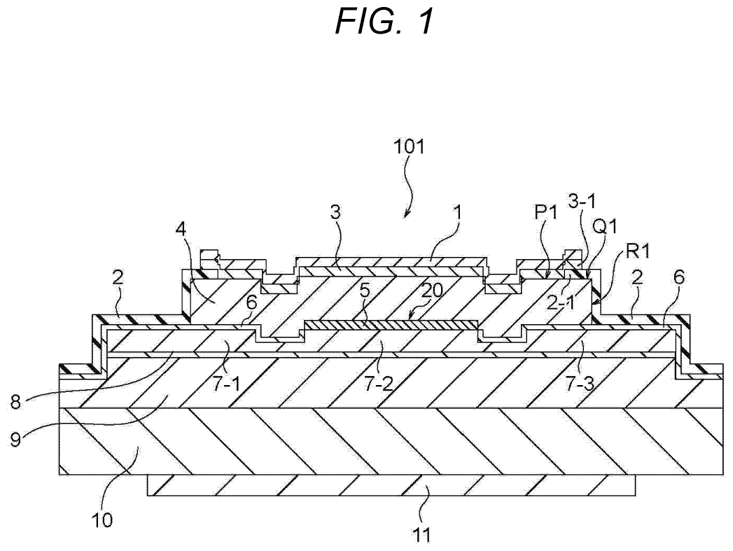

A semiconductor laser according to a first embodiment (Example 1 of a semiconductor laser) of the present technology will be described with reference to FIG. 1.

FIG. 1 is a view illustrating a configuration example of the semiconductor laser according to the first embodiment of the present technology, and specifically, is a cross-sectional view illustrating a semiconductor laser 101.

The semiconductor laser 101 includes an n-type electrode 11, a substrate (n-type GaN substrate) 10, a first cladding layer 9 of a first conductivity type (n-type cladding layer or n-type GaN layer), an active layer 8, a second cladding layer 7 of a second conductivity type (p-type cladding layer or p-type GaN layer (p-type GaN layers 7-1 to 7-3)), and a contact layer (p-type contact layer in FIG. 1, and the same applies hereinafter) (not illustrated) which are laminated in this order from the bottom (from the lower side in FIG. 1). Note that the n-type electrode 11 in the semiconductor laser 101 may correspond to a first electrode.

In the semiconductor laser 101, a transparent conductive film 5 (p-type electrode) is laminated on an upper portion (the upper side in FIG. 1) of the contact layer (not illustrated), a pad metal 4 is laminated on the contact layer (not illustrated) (the transparent conductive film 5), and a barrier metal 3 and a bonding metal 1 are laminated in this order on the pad metal 4. Note that the transparent conductive film 5 in the semiconductor laser 101 may correspond to a second electrode.

A part of an upper portion of the pad metal 4 (a portion denoted by reference sign Q1) and a side portion of the pad metal 4 (a portion denoted by reference sign R1) are covered with the insulating film 2, and a part of the upper portion of the pad metal 4 (a portion denoted by reference sign P1) is covered with the barrier metal 3.

A part (insulating film 2-1) of the insulating film 2 covering a part of the upper portion of the pad metal 4 and a part (barrier metal 3-1) of the barrier metal covering a part of the upper portion of the pad metal 4 are formed in this order from the pad metal 4 side. That is, the barrier metal 3-1 overlaps (is laminated on) the upper portion of the insulating film 2-1.

Although the overlap between the insulating film 2-1 and the barrier metal 3-1 has been described at a right end (the right side in FIG. 1) of the semiconductor laser 101 as described above, a part of the insulating film 2 and a part of the barrier metal 3 overlap each other (are laminated) in a similar state even at a left end (left side in FIG. 1) of the semiconductor laser 101.

The semiconductor laser 101 having a laminated structure includes a ridge portion 20 having a protruding shape, and the ridge portion 20 extends in a resonator direction (from the front side to the back side of the paper surface in FIG. 1). The ridge portion 20 is formed by removing a part of the p-type cladding layer (p-type GaN layer) 7 (7-1 to 7-3) and a part of the contact layer (not illustrated) by etching such as reactive ion etching (RIE). A width of the ridge portion 20 is, for example, 0.5 μm to 100 μm, and preferably 30 to 50 μm.

Both ends (left end and right end in FIG. 1) of the semiconductor laser 101 illustrated in FIG. 1 are removed by etching such as reactive ion etching (RIE) for element isolation. The etching extends in the resonator direction (from the front side to the back side of the paper surface in FIG. 1), but it is not always necessary to etch all of both ends. The etching etches and removes the p-type GaN layer 7 (7-1 to 7-3) until reaching the n-type GaN layer 9. A depth of the etching is, for example, 0.5 μm to 5 μm, and preferably 1 μm or more. A width of the etching is, for example, 1 μm to 50 μm, and preferably 10 μm or more on one side.

The pad metal 4 is laminated on the ridge portion 20. Moreover, the insulating film 2 (insulating film 2-1) is formed on the pad metal 4. The insulating film 2 is deposited by a deposition method with good step coverage such as a sputtering method. Next, the insulating film 2 on the upper portion of the pad metal 4 is etched in order to secure an electrical connection. A pattern smaller than that of the pad metal 4 is used as an etching pattern, and the insulating film 2 (insulating film 2-1) covering an edge of the pad metal 4 is not etched. Therefore, the side portion (side surface) of the pad metal 4 has a shape that is always covered with the insulating film 2, and a structure in which the insulating film 2-1 covers a part of the upper portion (planar portion) of the pad metal is obtained.

The barrier metal 3 and the bonding metal 1 are formed on the insulating film 2 (insulating film 2-1). A pattern is smaller than the pad metal 4 and larger than the pattern used for etching of the insulating film 2. Therefore, a part of the barrier metal 3-1 is in contact with a flat portion of the insulating film 2-1 on the pad metal 4 as described above.

The content described above for the semiconductor laser of the first embodiment (Example 1 of the semiconductor laser) according to the present technology can be applied to a method for manufacturing a semiconductor laser and a semiconductor laser of a second embodiment according to the present technology as described later unless there is a particular technical contradiction.

### 3. Second Embodiment (Example 1 of Method for Manufacturing Semiconductor Laser and Example 2 of Semiconductor Laser)

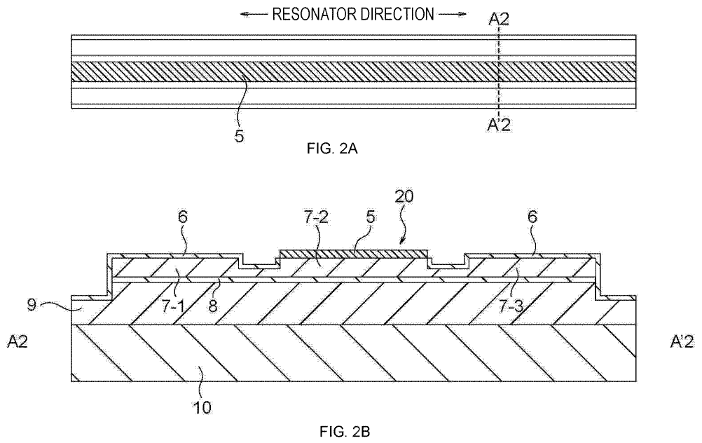

The method for manufacturing a semiconductor laser and the semiconductor laser according to the second embodiment (Example 1 of a method for manufacturing a semiconductor laser and Example 2 of a semiconductor laser) of the present technology will be described with reference to FIGS. 2 to 6.

FIG. 2 is a view for describing the method for manufacturing a semiconductor laser of the second embodiment to which the present technology is applied. Specifically, FIG. 2A is a plan view after a current confinement film 6 on an upper portion of the ridge portion 20 has been etched (the left-right direction in FIG. 2A is the resonator direction), and FIG. 2B is a cross-sectional view after the current confinement film 6 on the upper portion of a ridge Rd2 has been etched, the cross-sectional view taken along line A2-A′2 illustrated in FIG. 2A.

Description will be made with reference to FIGS. 2A and 2B.

As illustrated in FIG. 2A, the transparent conductive film 5 is formed to extend in a direction perpendicular to line A2-A′2 and in the resonator direction (the left-right direction in FIG. 2A).

The n-type cladding layer (n-type GaN layer) 9, an n-side guide layer (not illustrated), the active layer 8, a p-side guide layer (not illustrated), the p-type cladding layer (p-type GaN layer) 7 (7-1 to 7-3), and the contact layer (not illustrated) are sequentially laminated on the substrate (n-type GaN free-standing substrate) 10 by, for example, a metal organic chemical vapor deposition (MOCVD) method (a laminated structure body illustrated in FIG. 2B is formed).

Next, a trench for element isolation is formed at both ends of the element (the laminated structure body described above). For example, an etching mask layer including SiO₂, SiN, or the like is formed on the laminated structure body by a vapor deposition method, a sputtering method, or the like. For example, SiO₂ is used in the present embodiment. The etching mask layer is formed by performing pattern formation using photolithography, and the etching mask layer at a resist opening is removed by a reactive ion etching (RIE) method using a fluorine-based gas or hydrofluoric acid-based wet etching. Next, the p-type GaN layer 7 (7-1 to 7-3) is etched by a reactive ion etching (RIE) method using a chlorine-based gas to remove a part of the laminated structure body until reaching the n-type GaN layer 9.

Next, the etching mask layer is removed by hydrofluoric acid-based wet etching, and the transparent conductive film 5 is formed on the laminated structure body by, for example, a vapor deposition method, a sputtering method, or the like. Examples of the transparent conductive film 5 include indium tin oxide (ITO), indium titanium oxide (ITiO), Al₂O₃—ZnO (AZO), InGaZnOx (IGZO), and the like. Subsequently, at least a part of each of the transparent conductive film 5, the contact layer (not illustrated), and the p-type cladding layer (p-type GaN layer) 7 (7-1 to 7-3) is removed by a reactive ion etching (RIE) method or the like. As a result, the ridge portion (ridge structure) 20 having a protruding shape is formed.

Next, the current confinement layer 6 is formed on the laminated structure body (etched portion, the ridge portion 20, and the like) by a vapor deposition method, a sputtering method, or the like. The current confinement layer 6 includes, for example, SiO₂, SiN, Al₂O₃, or the like. Subsequently, only the current confinement layer 6 on the upper portion of the ridge 20 is removed by a reactive ion etching (RIE) method using a fluorine-based gas or wet etching using a hydrofluoric acid system. This enables an electrical connection with the pad metal 4 formed on the ridge portion 20.

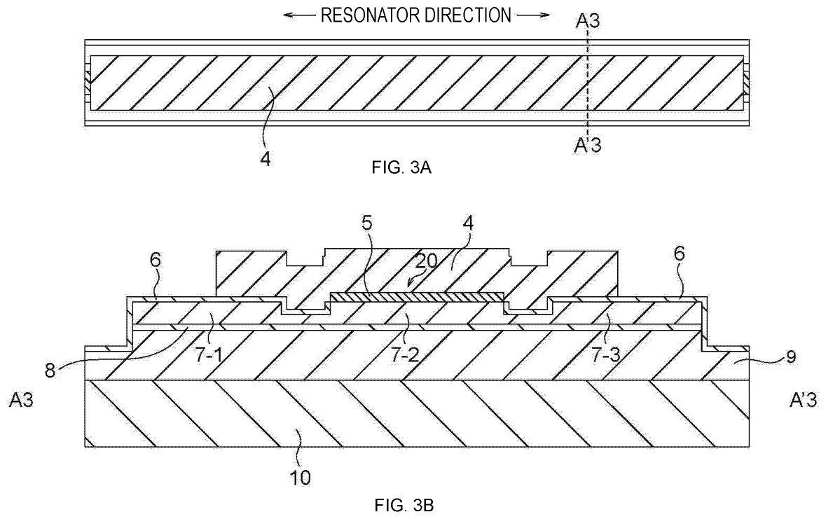

FIG. 3 is a view for describing the method for manufacturing a semiconductor laser according to the second embodiment to which the present technology is applied. Specifically, FIG. 3A is a plan view after formation of the pad metal 4 (the left-right direction in FIG. 3A is the resonator direction), and FIG. 3B is a cross-sectional view after formation of the pad metal 4, the cross-sectional view taken along line A3-A′3 illustrated in FIG. 2A.

Description will be made with reference to FIGS. 3A and 3B.

As illustrated in FIG. 3A, the pad metal 4 is formed to extend in a direction perpendicular to line A3-A′3 and in the resonator direction (the left-right direction in FIG. 3A).

Next, the pad metal 4 is formed on the laminated structure body formed in FIG. 2. The pad metal is deposited by a vapor deposition method, a sputtering method, or the like, and is subjected to pattern formation by, for example, a lift-off method. The pattern formation may be performed by removing an unnecessary portion by a reactive ion etching (RIE) method or a milling method. The pad metal 4 is formed by laminating titanium (Ti), palladium (Pd), platinum (Pt), and gold (Au) from the laminated structure body side, but only needs to be electrically connected to the upper surface of the ridge portion 20 and is not necessarily limited to this configuration. A thickness of titanium (Ti) may be, for example, 2 nm or more and 100 nm or less. A thickness of palladium (Pd) may be, for example, 10 nm or more and 300 nm or less. A thickness of platinum (Pt) may be, for example, 10 nm or more and 300 nm or less. A thickness of gold (Au) may be, for example, 300 nm or more and 3000 nm or less.

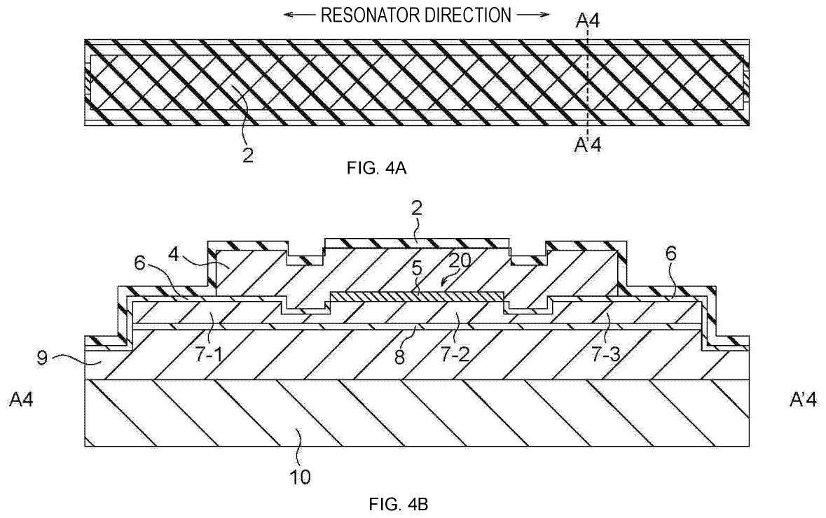

FIG. 4 is a view for describing the method for manufacturing a semiconductor laser according to the second embodiment to which the present technology is applied. Specifically, FIG. 4A is a plan view after formation of the insulating film 2 (the left-right direction in FIG. 4A is the resonator direction), and FIG. 4B is a cross-sectional view after formation of the insulating film 2, the cross-sectional view taken along line A4-A′4 illustrated in FIG. 4A.

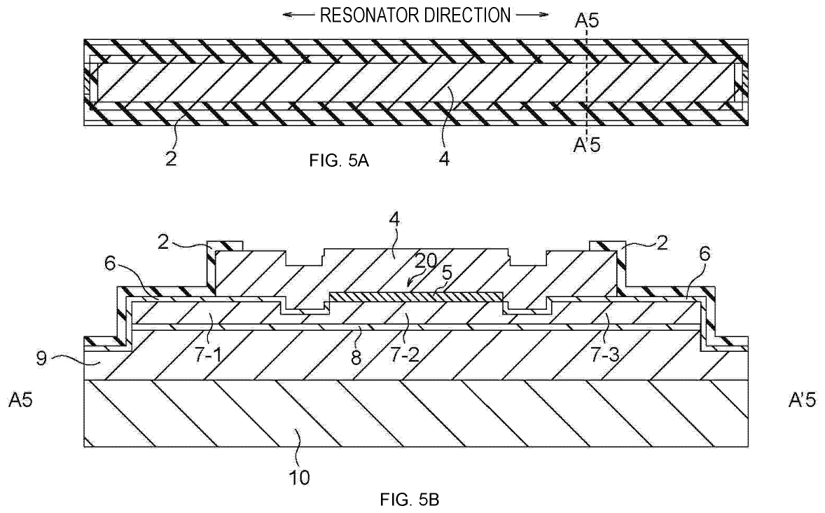

FIG. 5 is a view for describing the method for manufacturing a semiconductor laser according to the second embodiment to which the present technology is applied. Specifically, FIG. 5A is a plan view after the insulating film 2 has bene etched (the left-right direction in FIG. 5A is the resonator direction), and FIG. 5B is a cross-sectional view after the insulating film 2 has been etched, the cross-sectional view taken along line A5-A′5 illustrated in FIG. 5A.

Description will be made with reference to FIGS. 4 and 5.

As illustrated in FIG. 4A, the insulating film 2 is formed to extend in a direction perpendicular to line A4-A′4 and in the resonator direction (the left-right direction in FIG. 4A). Thereafter, the insulating film 2 is etched, and as illustrated in FIG. 5A, the pad metal 4 is formed to extend in a direction perpendicular to line A5-A′5 and in the resonator direction (the left-right direction in FIG. 5A), and the insulating film 2 is formed on the inner periphery and the outer periphery of the pad metal 4.

The insulating film 2 is formed after the pad metal 4 has been formed. The insulating film 2 is deposited on the laminated structure body (entire element surface) formed in FIG. 3, and the insulating film 2 formed on the upper portion of the pad metal 4 is etched in order to obtain the electrical connection with the pad metal 4. An etching pattern is smaller than a pattern of the pad metal 4, and a portion of the edge (end portion) of the pad metal 4 is not etched. Therefore, the entire side portion (side surface) of the pad metal 4 is covered with the insulating film 2. The etching is removed by a reactive ion etching (RIE) method using a fluorine-based gas or wet etching using a hydrofluoric acid-based gas.

The insulating film 2 may be a single layer of SiN, or may be formed by laminating a SiN layer and a layer (insulating layer) including other materials such as SiO₂. A thickness of the insulating film 2 may be 10 nm or more and 500 nm or less, and is preferably 200 nm or more.

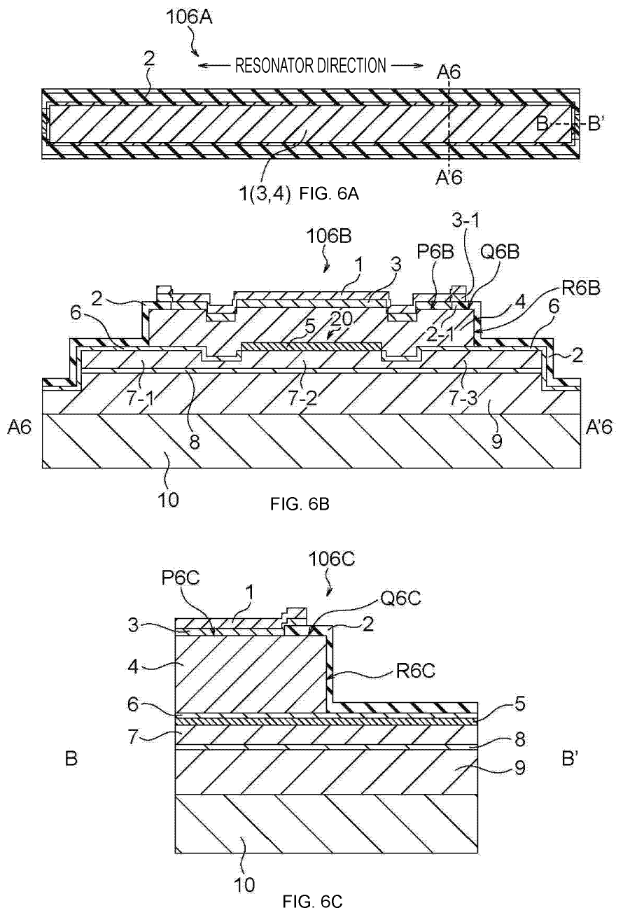

FIG. 6 is a view illustrating a configuration example of a semiconductor laser manufactured according to the method for manufacturing a semiconductor laser of the second embodiment to which the present technology is applied.

Specifically, FIG. 6A is a plan view of a semiconductor laser 106 (a semiconductor laser 106A in FIG. 6A) manufactured by forming the barrier metal 3 on the upper portion of the pad metal 4, and thereafter, forming the bonding metal 1 on the upper portion of the barrier metal 3 (the left-right direction in FIG. 6A is the resonator direction). FIG. 6B is a cross-sectional view of the semiconductor laser 106 (a semiconductor laser 106B in FIG. 6B) manufactured by forming the barrier metal 3 on the upper portion of the pad metal 4, and thereafter, forming the bonding metal 1 on the upper portion of the barrier metal 3, the cross-sectional view taken along line A6-A′6 illustrated in FIG. 6A. FIG. 6C is a cross-sectional view of the semiconductor laser 106 (a semiconductor laser 106C in FIG. 6C) manufactured by forming the barrier metal 3 on the upper portion of the pad metal 4, and thereafter, forming the bonding metal 1 on the upper portion of the barrier metal 3, the cross-sectional view taken along line B-B′ illustrated in FIG. 6A, and is a view illustrating a laser emitting end portion in the resonator direction.

Description will be made with reference to FIGS. 6A to 6C.

As illustrated in FIG. 6A, the bonding metal 1, the barrier metal 3, and the pad metal 4 are formed to extend in a direction perpendicular to line A6-A′6 and in the resonator direction (the left-right direction in FIG. 6A). Then, the insulating film 2 is formed on the inner periphery and the outer periphery of the bonding metal 1, the barrier metal 3, and the pad metal 4.

The barrier metal 3 and the bonding metal 1 are formed in this order on the pad metal 4. Each of the barrier metal 3 and the bonding metal 1 is formed by a vapor deposition method, a sputtering method, or the like, and a pattern thereof is formed by a lift-off method. The respective metals (the barrier metal 3 and the bonding metal 1) may be continuously deposited, or may be individually deposited and formed. In the present embodiment, the deposition is continuously performed.

The pattern is smaller than the pad metal 4 and larger than the pattern used for etching the insulating film 2. Therefore, as indicated by reference sign Q6B in FIG. 6B, a part (that is, the barrier metal 3-1) of the barrier metal 3 is in contact with a flat portion of the insulating film 2-1 formed on the upper portion of the pad metal 4 so as to overlap.

The barrier metal 3 may have a laminated structure including at least two layers of a titanium (Ti) layer, a platinum (Pt) layer, a molybdenum (Mo) layer, and a tungsten (W) layer. Furthermore, the barrier metal 3 may have a single-layer structure including any one layer of a titanium (Ti) layer, a platinum (Pt) layer, a molybdenum (Mo) layer, and a tungsten (W) layer. In the present embodiment, a single layer of titanium (Ti) is formed. A thickness of the single layer of titanium (Ti) may be 100 nm or more and 500 nm or less, and is preferably 200 nm or more.

The bonding metal 1 may have a laminated structure including at least two layers of a titanium (Ti) layer, a platinum (Pt) layer, and a gold (Au) layer, or may be a single layer of gold (Au). In the present embodiment, the single layer of Au constituting the bonding metal 1 is formed continuously to the single layer of Ti constituting the barrier metal 3. A thickness of the single layer of Au may be 100 nm or more and 500 nm or less, and is preferably 300 nm or more.

Refer to FIG. 6B. The semiconductor laser 106B includes the substrate (n-type GaN substrate) 10, the first cladding layer 9 of the first conductivity type (n-type cladding layer or n-type GaN layer), a first guide layer (n-side guide layer) (not illustrated), the active layer 8, a second guide layer (p-side guide layer) (not illustrated), the second cladding layer 7 of the second conductivity type (p-type cladding layer or p-type GaN layer (the p-type GaN layers 7-1 to 7-3)), and a contact layer (p-type contact layer in FIG. 6B, and the same applies hereinafter) (not illustrated) which are laminated in this order from the bottom (from the lower side in FIG. 6B).

In the semiconductor laser 106B, the transparent conductive film 5 (p-type electrode) is laminated on an upper portion of the contact layer (not illustrated), the pad metal 4 is laminated on the contact layer (not illustrated) (the transparent conductive film 5), and the barrier metal 3 and a bonding metal 1 are laminated in this order on the pad metal 4. Note that the transparent conductive film 5 in the semiconductor laser 106B may correspond to a second electrode.

A part of an upper portion of the pad metal 4 (a portion denoted by reference sign Q6B) and a side portion of the pad metal 4 (a portion denoted by reference sign R6B) are covered with the insulating film 2, and a part of the upper portion of the pad metal 4 (a portion denoted by reference sign P6B) is covered with the barrier metal 3.

A part (insulating film 2-1) of the insulating film 2 covering a part of the upper portion of the pad metal 4 and a part (barrier metal 3-1) of the barrier metal covering a part of the upper portion of the pad metal 4 are formed in this order from the pad metal 4 side. That is, the barrier metal 3-1 overlaps (is laminated on) the upper portion of the insulating film 2-1.

Although such an overlap between the insulating film 2-1 and the barrier metal 3-1 has been described at a right end (the right side in FIG. 6B) of the semiconductor laser 106B as described above, the insulating film 2 and the barrier metal 3 overlap each other (are laminated) in a similar state even at a left end (left side in FIG. 6B) of the semiconductor laser 106B.

Refer to FIG. 6C. The semiconductor laser 106C includes the substrate (n-type GaN free-standing substrate) 10, the first cladding layer 9 of the first conductivity type (n-type cladding layer or n-type GaN layer), a first guide layer (n-side guide layer) (not illustrated), the active layer 8, a second guide layer (p-side guide layer) (not illustrated), the second cladding layer 8 of the second conductivity type (p-type cladding layer or p-type GaN layer (the p-type GaN layers 7-1 to 7-3)), and a contact layer (p-type contact layer in FIG. 6C, the same applies hereinafter) (not illustrated), the transparent conductive film 5 (p-type electrode), and the current confinement film 6 which are laminated in this order from the bottom (from the lower side in FIG. 6B). Note that the transparent conductive film 5 in the semiconductor laser 106C may correspond to a second electrode.

The pad metal 4 is laminated on the current confinement film 6, and the barrier metal 3 and the bonding metal 1 are laminated in this order on the pad metal 4.

A part of an upper portion of the pad metal 4 (a portion indicated by reference sign Q6C), a side portion of the pad metal 4 (a portion indicated by reference sign R6CB), and an upper portion of the current confinement film 6 extending rightward from a right end side of the pad metal 4 are covered with the insulating film 2. Furthermore, a part of the upper portion of the pad metal 4 (a portion indicated by reference sign P6C) is covered with the barrier metal 3.

A part of the insulating film 2 covering a part of the upper portion (a right end of the upper portion) of the pad metal 4 and a part of the barrier metal 3 covering a part of an upper portion of the right end (a right end of the upper portion) of the pad metal 4 are formed in this order from the pad metal 4 side. That is, the barrier metal 3 overlaps (is laminated on) the upper portion of the insulating film 2.

According to the semiconductor lasers 106B and 106C, the pad metal 4 is covered with the insulating film 2 with good coverage, so that diffusion of an Sn-based solder is suppressed. Furthermore, when the Sn solder is diffused to the pad metal 4 near a laser emitting end, a particularly large adverse effect is exert on laser characteristics and reliability, but the semiconductor laser 106C can suppress this adverse effect.

Next, the substrate (n-type GaN free-standing substrate) 10 is polished to a thickness suitable for cleavage, and an n-electrode (not illustrated) is formed by, for example, a lift-off method. Note that the n-electrode is illustrated as the n-electrode 11 in FIG. 1 as described above. Subsequently, the substrate (n-type GaN free-standing substrate) 10 is cleaved into a bar shape, and an exposed end surface portion is coated. Moreover, the bar is cut out into chips to manufacture a finished product of the semiconductor lasers 106 (106A to 106C).

The content described above for the method for manufacturing a semiconductor laser and the semiconductor laser according to the second embodiment (Example 1 of the method for manufacturing a semiconductor laser and Example 2 of the semiconductor laser) of the present technology can be applied to the semiconductor laser according to the first embodiment of the present technology described above unless there is a particular technical contradiction.

Note that embodiments according to the present technology are not limited to the above-described embodiments, and various modifications can be made without departing from the gist of the present technology.

Furthermore, effects described in the present specification are merely examples and are not limited, and there may be other effects.

Furthermore, the present technology can also have the following configurations.
[1]
   A semiconductor laser including a substrate, a first cladding layer of a first conductivity type, an active layer, a second cladding layer of a second conductivity type, and a pad metal in this order,
   in which an upper portion of the pad metal on a side of the pad metal opposite to a side closer to the substrate and a side portion of the pad metal are covered with an insulating film and a barrier metal, and
   the barrier metal and a bonding metal are disposed in this order on the pad metal on the side opposite to the side of the pad metal closer to the substrate.
[2]
   The semiconductor laser according to [1], in which
   the insulating film covers a part of the upper portion and the side portion of the pad metal, and
   the barrier metal covers a part of the upper portion of the pad metal.
[3]
   The semiconductor laser according to [1], in which
   the insulating film covers a part of the upper portion and the side portion of the pad metal,
   the barrier metal covers a part of the upper portion of the pad metal, and
   a part of the insulating film covering the part of the upper portion of the pad metal and a part of the barrier metal covering the part of the upper portion of the pad metal are formed in this order from a side closer to the pad metal.
[4]
   The semiconductor laser according to [1], in which
   the insulating film covers the side portion of the pad metal, and
   the barrier metal covers the upper portion of the pad metal.
[5]
   The semiconductor laser according to [1], in which
   the insulating film covers a part of the upper portion and the side portion of the pad metal,
   the barrier metal covers a part of the upper portion of the pad metal, and
   an end portion of the insulating film covering the part of the upper portion of the pad metal and an end portion of the barrier metal covering the part of the upper portion of the pad metal are in contact with each other.
[6]
   The semiconductor laser according to [1], in which
   the insulating film covers a part of the side portion of the pad metal, and
   the barrier metal covers the upper portion and a part of the side portion of the pad metal.
[7]
   The semiconductor laser according to any one of [1] to [6], in which
   a first guide layer is disposed between the first cladding layer and the active layer, and
   a second guide layer is disposed between the second cladding layer and the active layer.
[8]
   The semiconductor laser according to any one of [1] to [7], in which a contact layer and a second electrode are disposed in this order from the side closer to the substrate between the second cladding layer and the pad metal.
[9]
   The semiconductor laser according to [8], in which the second electrode is a transparent conductive film.
[10]
   the insulating film has a laminated structure including at least two layers, and
   The semiconductor laser according to any one of [1] to [9], in which at least one of the at least two layers of the insulating film is a SiN layer.
[11]
   The semiconductor laser according to any one of [1] to [10], in which
   the barrier metal has a laminated structure including at least two layers, and
   at least one layer of the at least two layers of the barrier metal is a Ti layer.
[12]
   The semiconductor laser according to any one of [1] to [11], being a nitride semiconductor laser.

### REFERENCE SIGNS LIST

1 Bonding metal
2 Insulating film
3 Barrier metal
4 Pad metal
5 Transparent conductive film (second electrode)
6 Current confinement film
7 p-type cladding layer (second cladding layer of second conductivity type)
8 Active layer
9 n-type cladding layer (first cladding layer of first conductivity type)
10 Substrate (n-type GaN substrate)
11 n-type electrode (first electrode)
101.106A, 106B, 106C Semiconductor laser

1. A semiconductor laser comprising a substrate, a first cladding layer of a first conductivity type, an active layer, a second cladding layer of a second conductivity type, and a pad metal in order,
wherein an upper portion of the pad metal on a side of the pad metal opposite to a side closer to the substrate and a side portion of the pad metal are covered with an insulating film and a barrier metal, and
the barrier metal and a bonding metal are disposed in order on the pad metal on the side of the pad metal opposite to the side closer to the substrate.

2. The semiconductor laser according to claim 1, wherein
the insulating film covers a part of the upper portion and the side portion of the pad metal, and
the barrier metal covers a part of the upper portion of the pad metal.

3. The semiconductor laser according to claim 1, wherein
the insulating film covers a part of the upper portion and the side portion of the pad metal,
the barrier metal covers a part of the upper portion of the pad metal, and
a part of the insulating film covering the part of the upper portion of the pad metal and a part of the barrier metal covering the part of the upper portion of the pad metal are formed in order from a side closer to the pad metal.

4. The semiconductor laser according to claim 1, wherein
the insulating film covers the side portion of the pad metal, and
the barrier metal covers the upper portion of the pad metal.

5. The semiconductor laser according to claim 1, wherein
the insulating film covers a part of the upper portion and the side portion of the pad metal,
the barrier metal covers a part of the upper portion of the pad metal, and
an end portion of the insulating film covering the part of the upper portion of the pad metal and an end portion of the barrier metal covering the part of the upper portion of the pad metal are in contact with each other.

6. The semiconductor laser according to claim 1, wherein
the insulating film covers a part of the side portion of the pad metal, and
the barrier metal covers the upper portion and a part of the side portion of the pad metal.

7. The semiconductor laser according to claim 1, wherein
a first guide layer is disposed between the first cladding layer and the active layer, and
a second guide layer is disposed between the second cladding layer and the active layer.

8. The semiconductor laser according to claim 1, wherein a contact layer and a second electrode are disposed in order from the side closer to the substrate between the second cladding layer and the pad metal.

9. The semiconductor laser according to claim 8, wherein the second electrode is a transparent conductive film.

10. The semiconductor laser according to claim 1, wherein
the insulating film has a laminated structure including at least two layers, and
at least one layer of the at least two layers of the insulating film is a SiN layer.

11. The semiconductor laser according to claim 1, wherein
the barrier metal has a laminated structure including at least two layers, and
at least one layer of the at least two layers of the barrier metal is a Ti layer.

12. The semiconductor laser according to claim 1, being a nitride semiconductor laser.
